(19) United States
(12) Patent Application Publication
(10) Pub. No.: US 2026/0088257 A1
(43) Pub. Date: Mar. 26, 2026

(54) GAS INJECTOR ASSEMBLY WITH IMPROVED GAS MIXING

(71) Applicant: Applied Materials, Inc., Santa Clara, CA (US)

(72) Inventors: Muhannad Mustafa, Milpitas, CA (US); Aditya Chuttar, Sunnyvale, CA (US); Azhar ALI M.A, Bangalore (IN); Dhritiman Subha Kashyap, Bangalore (IN)

(21) Appl. No.: 18/897,892

(22) Filed: Sep. 26, 2024

(51) Int. Cl. H01J 37/32

(52) U.S. Cl. CPC H01J 37/32449; H01J 37/32357; H01J 2237/332

(57) ABSTRACT

Gas distribution inserts configured to deliver a gas in semiconductor manufacturing processing chambers are described. The gas distribution insert comprises a plurality of randomly oriented gas openings extending through the thickness of the inlet end wall. An inner gas channel extends from the outlet end wall face to the insert outlet end, and the inner gas channel is bounded by an inner gas channel sidewall. The gas distribution inserts include at least two gas inlets extending through the inner gas channel sidewall.

### TECHNICAL FIELD

Embodiments of the disclosure are directed to gas injectors for semiconductor manufacturing processing chambers. In particular, embodiments of the disclosure are directed to gas injectors with improved mixing for semiconductor manufacturing processing chambers.

### BACKGROUND

Reliably producing submicron and smaller features by the deposition of thin films is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Thin films are generally fabricated in substrate processing chambers adapted for performing various deposition, etch, and thermal processes, among other processes, upon substrates, such as silicon (Si) wafers, gallium arsenide (GaAs) wafers, glass, and sapphire. Various etch processes and deposition processes, including chemical vapor deposition (CVD) and atomic layer deposition (ALD), can be optimized by controlling the process conditions within the substrate processing chamber. In particular, during a deposition process, the chemical reaction rate is strongly impacted by substrate processing chamber pressure. As such, the ability to transition between and maintain precise target pressures within the processing chamber is critical to forming uniform deposition of thin films during semiconductor fabrication.

One method of controlling pressure within a substrate processing chamber relies on preserving gas uniformity before entering the funnel cavity of the gas distribution assembly. A current approach utilizes mechanical mixers, which often inhibits gas mixing uniformity before entering the funnel cavity and leads because current gas injectors use a cap insert that cannot ensure efficient gas mixing at wide range of process pressure for ALD or CVD processes.

Current cap inserts have tangential gas injection ports which creates a strong vortex inside a vacuum cavity. The strong vortex generates molecular separation according to the different gas molecules having different sizes. Centrifugal force separates and pushes larger molecules to the center and smaller molecules to edge. The centrifugal force also generates laminarity of the gas stream along a spiral path with slow gas diffusion for mixing. Accordingly, there is a need in the art for improved gas mixing for gas injectors of processing chambers.

### SUMMARY

One or more embodiments of the disclosure are directed to gas distribution insert configured to deliver a gas in a semiconductor manufacturing processing chamber. In one embodiment the gas distribution insert comprises a gas distribution insert inlet end and a gas distribution insert outlet end defining a gas distribution insert length, the insert inlet end including an inlet end wall including an inlet end wall face and an outlet end wall face, the inlet end wall face and the outlet end wall face defining a thickness of the inlet end wall. The gas distribution insert further comprises a plurality of randomly oriented gas openings extending through the thickness of the inlet end wall; an inner gas channel extending from the outlet end wall face to the insert outlet end, the inner gas channel bounded by an inner gas channel sidewall; and at least two gas inlets extending through the inner gas channel sidewall.

Additional embodiments of the disclosure pertain to gas distribution apparatus comprising the one or more embodiments of the gas distribution insert described herein and further comprising a gas distribution faceplate having a top surface and a bottom surface with a plurality of apertures extending through the gas distribution faceplate from the top surface to the bottom surface and in flow communication with the gas distribution insert.

Additional embodiments of the disclosure pertain to a semiconductor manufacturing processing chamber comprising the gas distribution apparatus described herein.

Additional embodiments of the disclosure further pertain to methods of processing a substrate in a semiconductor manufacturing processing chamber comprising flowing a processing gas through the gas distribution insert according to one or more embodiments described herein.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic view of a processing chamber in accordance with one or more embodiments of the disclosure;

FIG. 2 shows an expanded view of a prior art gas distribution assembly with a gas insert according to one or more embodiments of the disclosure;

FIG. 3 shows a side view of a gas distribution insert according to one or more embodiments of the disclosure, the internal structure of which is shown in dotted lines;

FIG. 4 shows a cross-sectional view of the gas insert of FIG. 3 taken through the center of the inner channel;

FIG. 5 shows a cross-sectional of the gas distribution insert of FIG. 3 taken along line 5-5’; and

FIG. 6 shows an isometric view of the gas insert of FIG. 3, the internal structure of which is shown in dotted lines.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A "substrate" as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term "substrate surface" is intended to include such underlayer as the context indicates. Thus, for example, where a film/layer or partial film/layer has been deposited onto a substrate surface, the exposed surface of the newly deposited film/layer becomes the substrate surface.

"Atomic layer deposition" or "cyclical deposition" as used herein refers to a process comprising the sequential exposure of two or more reactive compounds to deposit a layer of material on a substrate surface. "Atomic layer deposition" or "cyclical deposition" as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term "substantially" used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

Embodiments of the present disclosure provide improved gas mixing by disrupting laminar flow in the cap insert and providing turbulent flow. In one or more embodiments, turbulent flow is established without using a mechanical mixer and the attendant disadvantages of mechanical mixtures, which add surface area, limit fast purging capability and tend to generate cold spots in the cap insert, which are detrimental during ALD processes.

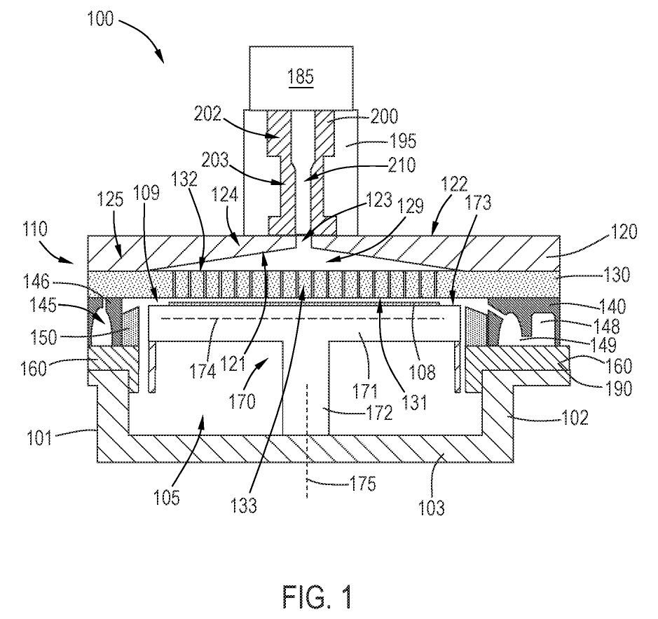

With reference to FIG. 1, one or more embodiments of the disclosure are directed to a semiconductor manufacturing processing chamber 100. The semiconductor manufacturing processing chamber 100 comprises a chamber body 101 having sidewalls 102 and a bottom wall 103 surrounding a chamber interior 105. The sidewall 102 and bottom wall 103 can be integrally formed or separate component connected together by any suitable connection or fastener known to the skilled artisan.

The semiconductor manufacturing processing chambers 100 of some embodiments includes a gas distribution assembly 110. The gas distribution assembly 110 comprises a backing plate 120 and a gas distribution faceplate 130. In some embodiments, the semiconductor manufacturing processing chamber 100 further comprises a pumping ring 140. In some embodiments, the pumping ring 140 is considered a separate part from the gas distribution assembly 110.

The chamber body 101, in conjunction with the gas distribution assembly 110 encloses the chamber interior 105 of the semiconductor manufacturing processing chamber 100. During processing, the chamber interior 105 of the semiconductor manufacturing processing chamber 100 is typically maintained at a controlled pressure (usually a low-pressure environment) using one or more gas inlet (not shown) and one or more exhaust (not shown). The skilled artisan will be familiar with the general construction of the chamber body 101 and the use of gas inlets and exhaust systems.

The backing plate 120 has a front surface 121 and a back surface 122 that define a thickness of the backing plate 120. The backing plate 120 has an inner portion 124 and an outer portion 125. The backing plate 120 contacts the gas distribution faceplate 130 at the outer portion 125.

The backing plate 120 has an inlet opening 123 in a center thereof. The inlet opening 123 extends through the thickness of the backing plate 120 from the back surface 122 to the front surface 121. The central axis of the backing plate 120 is defined at the center of the inlet opening 123. The outer peripheral edge of the inner portion 124 of the front surface 121 of some embodiments is concentric with the inlet opening 123. While the backing plate 120 of some embodiments has an oblong or non-symmetrical shape, the central axis remains at the center of the inlet opening 123 even if that is not the center of mass of the backing plate 120.

The front surface 121 of the backing plate 120 at the inner portion 124 has a concave shape. The concave shape of some embodiments has a linear slope from the inlet opening 123 to the outer peripheral edge of the inner portion 124 at the transition to the outer portion 125, as illustrated in the Figures. In some embodiments, the concave shape has a curved profile from the inlet opening 123 to the outer peripheral edge of the inner portion 124.

The gas distribution assembly 110 includes a gas distribution faceplate 130, which may also be referred to as a “showerhead”. The gas distribution faceplate 130 has a front surface 131 and a back surface 132 defining a thickness of the gas distribution faceplate 130. The gas distribution faceplate 130 has an inner portion 133 and an outer portion 134. The inner portion 133 of the gas distribution faceplate 130 aligns with the inner portion 124 of the backing plate 120 and the outer portion 134 of the gas distribution faceplate 130 aligns with the outer portion 125 of the backing plate 120. The inner portion 133 of the gas distribution faceplate 130 comprises a plurality of apertures 135 extending through the thickness of the gas distribution faceplate 130.

The backing plate 120 can be connected to the gas distribution faceplate 130 by any suitable mechanism known to the skilled artisan. For example, the backing plate 120 can be welded to the gas distribution faceplate 130. In some embodiments, the backing plate 120 is connected to the gas distribution faceplate 130 with a plurality of fasteners. Suitable fasteners include, but are not limited to, bolts with or without O-rings.

When the front surface 121 of the outer portion 125 of the backing plate 120 is in contact with the outer portion 134 of the back surface 132 of the gas distribution faceplate 130, a gas box plenum 129 is formed in the space between the front surface 121 of the inner portion 124 of the backing plate 120 and the inner portion 133 of the back surface 132 of the gas distribution faceplate 130.

In some embodiments, the gas box plenum 129 has a coating to improve chemical compatibility. In some embodiments, the coating covers the entire front surface 121 of the backing plate 120 and the entire back surface 132 of the gas distribution faceplate 130, including in the inlet opening 123 of the backing plate 120 and the plurality of apertures 135 of the gas distribution faceplate 130. In some embodiments, the coating is only on the portions of the backing plate 120 and gas distribution faceplate 130 that will come into contact with the process gases.

In some embodiments, the gas distribution assembly 110 further comprises a gas manifold 195 connected to the back surface 122 of the backing plate 120. The gas manifold 195 has a gas distribution insert 200 with an inner channel 210 aligned with the inlet opening 123 in the center of the backing plate 120. The inner channel 210 of some embodiments has an upper portion 202 and a lower portion 203. The upper portion 202 has a larger inner diameter than the inner diameter of the lower portion 203.

Conventional gas distribution assemblies either do not incorporate a gas insert or use a gas insert that suffers from insufficient gas mixing. During deposition, the non-uniform gas mixing is revealed as an entry port signature in the deposited film. The gas insert of the present disclosure advantageously provides efficient gas mixing at a wide range of process pressures for ALD processes, and improved co-flow in CVD processes.

One or more embodiments of the present disclosure provides gas distribution insert configured to deliver a gas in a semiconductor manufacturing processing chamber. The gas distribution insert comprises a gas distribution insert inlet end and a gas distribution insert outlet end defining a gas distribution insert length, the insert inlet end including an inlet end wall including an inlet end wall face and an outlet end wall face, the inlet end wall face and the outlet end wall face defining a thickness of the inlet end wall. The gas distribution insert further includes a plurality of randomly oriented gas openings extending through the thickness of the inlet end wall, and an inner gas channel extending from the outlet end wall face to the insert outlet end, the inner gas channel bounded by an inner gas channel sidewall. There are at least two gas inlets extending through the inner gas channel sidewall. As used herein according to one or more embodiments, "random" and "randomly" with respect to the orientation of the gas openings refer to the gas openings having no specific pattern or arrangement.

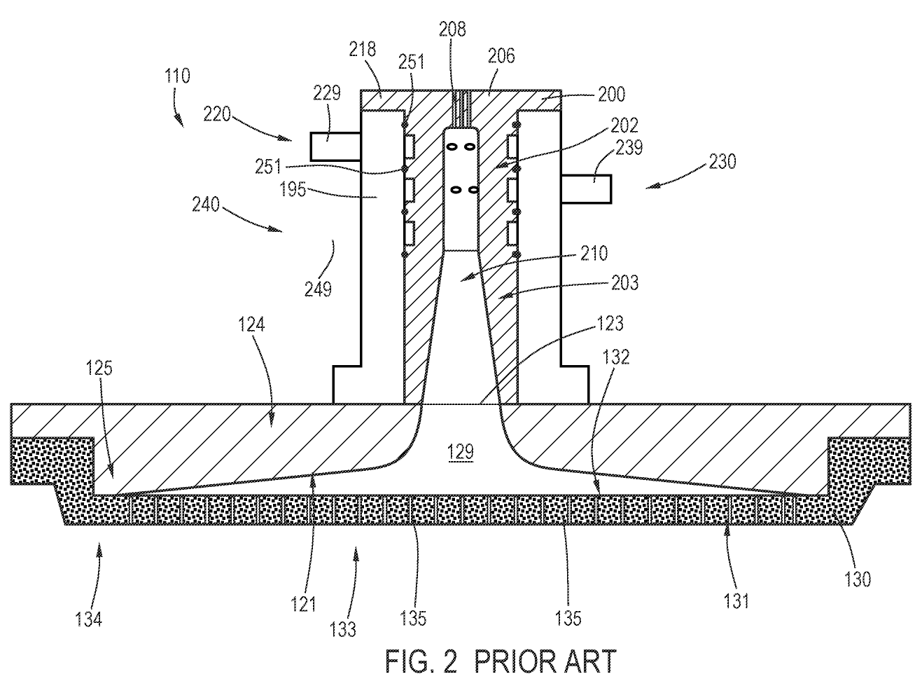

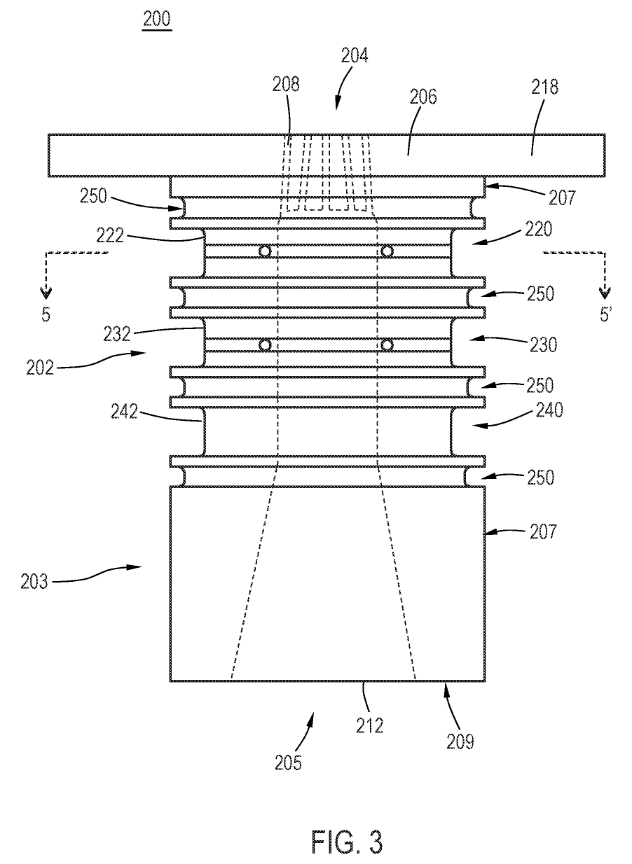

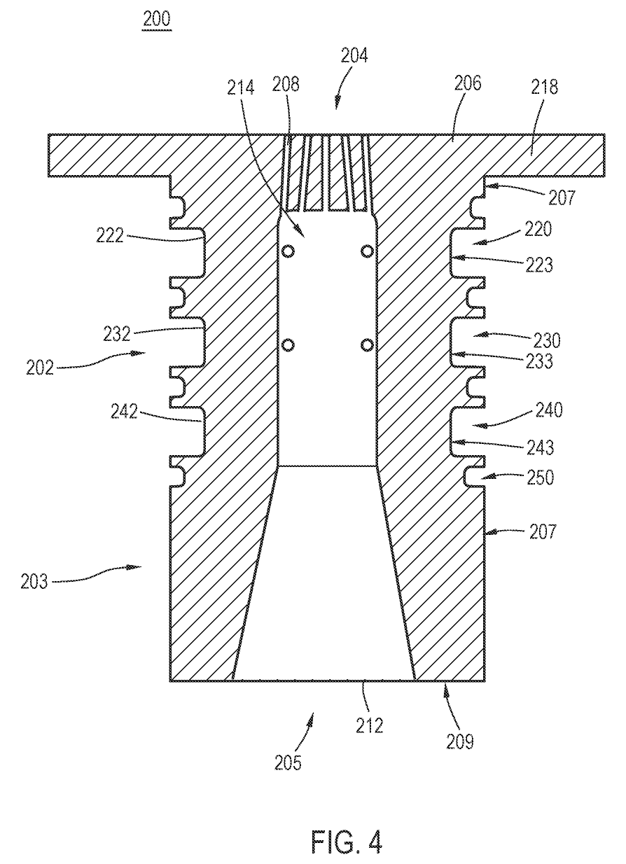

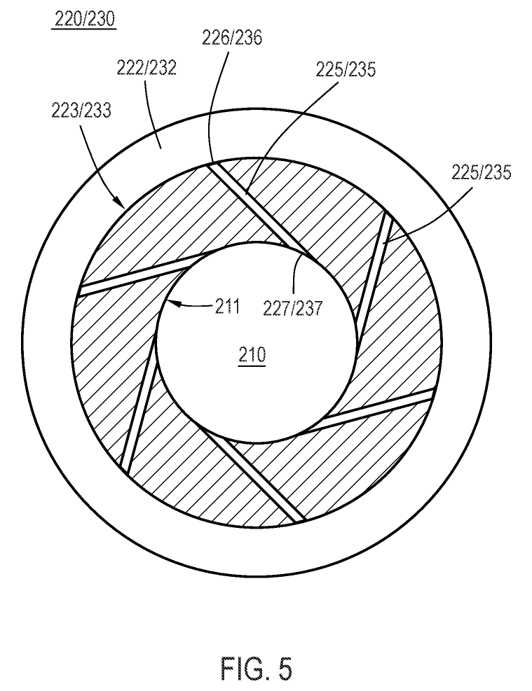

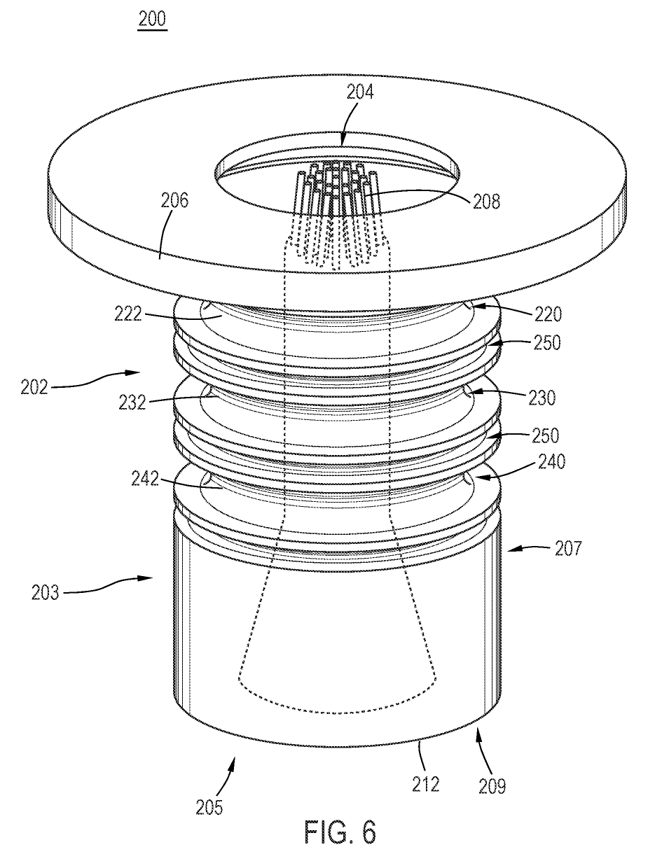

FIG. 2 shows an expanded view of a prior art gas distribution assembly 110 with a gas distribution insert 200 according to one or more embodiments of the disclosure. FIG. 3 shows a side view of a gas distribution insert 200 according to one or more embodiments of the disclosure with the randomly oriented gas openings, the internal structure of which is shown in dotted lines. FIG. 4 shows a cross-sectional view of the gas distribution insert 200 of FIG. 3 taken through the center of the inner channel 210. FIG. 5 shows a cross-sectional view of the gas distribution insert 200 of FIG. 3 taken along line 5-5’. FIG. 6 shows an isometric view of the gas insert of FIG. 3, the internal structure of which is shown in dotted lines.

With reference to FIGS. 2 through 6, one or more embodiments of the disclosure are directed to a gas distribution insert 200 configured to deliver gas in a semiconductor manufacturing processing chamber 100. The gas distribution insert 200 comprises a plurality of gas injection levels 220, 230 providing a gas flow to an inner channel 210 within the gas distribution insert 200. Each of the gas flows are directed in a rotational direction within the inner channel 210, with the gas level closest to the outlet end 205 of the gas distribution insert 200 directs a gas flow in an opposite rotational direction than the other gas injection levels.

The embodiments illustrated in the Figures have three gas injection levels. However, the skilled artisan will recognize that there can be more than three gas injection levels with at least the gas injection level closest to the outlet end 205 of the gas distribution insert 200 directing a gas flow in the opposite rotational direction from at least one of the gas injection levels above. In some embodiments, the gas injection level closest to the outlet end 205 of the gas distribution insert 200 directs a gas flow in a direction opposite the other gas injection levels. In some embodiments, at least two gas injection levels direct gas flows opposite at least two other gas injection levels. For example, in an alternating arrangement, or stacked with the at least two opposite flow injection levels closest to the outlet end 205.

In some embodiments, the plurality of gas injection levels comprises an inlet end gas injection level 220 closest to the inlet end 201 of the gas distribution insert 200 and the gas injection level 230 closest to the outlet end 205 of the gas distribution insert 200. The inlet end 201 and outlet end 205 define a length of the gas distribution insert 200.

In the illustrated embodiment, there are two gas injection levels: an inlet end gas injection level 220 closest to the inlet end 201 of the 200, an outlet gas injection level 230. The outlet end gas injection level 230 is closest to the outlet end 205 of the gas distribution insert 200. Stated differently, the outlet end gas injection level 230 is furthest from the inlet end 201 of the gas distribution insert 200.

The gas distribution insert 200 has an outer peripheral surface 207 that, in combination with the gas manifold 195 creates a plurality of injection level recesses. In the illustrated embodiment, a plurality of peripheral recesses is formed in the outer peripheral surface 207 of the gas distribution insert 200 so that when the gas distribution insert 200 is within the gas manifold 195, a plurality of injection level recesses is formed. Stated differently, the gas manifold 195 is around the gas distribution insert 200, and the gas manifold 195 cooperatively interacts with the gas distribution insert 200 to form peripheral recesses of the gas injection levels. The skilled artisan will recognize the complementary nature of the gas distribution insert 200 within the gas manifold 195 and the injection level recesses can be formed on the inner surface of the gas manifold 195 so that the injection levels are formed upon assembly with the gas distribution insert 200.

In the illustrated embodiment, each gas injection level 220, 230 comprises a peripheral recess 222, 232 in the outer peripheral surface 207 of the gas distribution insert 200. Each peripheral recess 222, 232 comprises a plurality of angled apertures 225, 235 extending from a bottom surface 223, 233 of the respective peripheral recess 222, 232 to the inner channel 210. Each of the angled apertures 225, 235 have an outer opening 226, 236 as the bottom surface 223, 233 of the respective peripheral recess 222, 232 and an inner opening 227, 237 at the channel wall 211 of the inner channel 210.

The number of angled apertures 225, 235 in each of the peripheral recesses 222, 232 can affect the gas flow and mixing efficiency within the 210. In some embodiments, the inlet end gas injection level 220 comprises in the range of 4 to 10 angled apertures 225 spaced around the bottom surface 223 of the peripheral recess 222. In some embodiments, the outlet end gas injection level 230 comprises in the range of 4 to 10 angled apertures 235 spaced around the bottom surface 233 of the peripheral recess 232. In some embodiments, there is the same number of angled apertures 225 in the inlet end gas injection level 220 as the number of angled apertures 235 in the outlet end gas injection level 230. In some embodiments, there are a different number of angled apertures 225 in the inlet end gas injection level 220 than angled apertures 235 in the outlet end gas injection level 230.

The angled apertures 225 are illustrated as being evenly spaced around the bottom surface 223 of the inlet end gas injection level 220 and the angled apertures 235 are evenly spaced around the bottom surface 233 of the outlet end gas injection level 230. However, the skilled artisan will recognize that the distribution of angled apertures is not limited to being evenly spaced. The cross-sectional view of FIG. 5 taken along line 5-5’ of FIG. 3 could also be considered the cross-sectional view through the outlet end gas injection level 230 if the number and angles of the angled apertures are the same for the two levels. In some embodiments, the angled apertures 235 of the outlet end gas injection level 230 are vertically aligned with the angled apertures 225 of the inlet end gas injection level 220 so that cross-sectional views through the inlet end gas injection level 220 and outlet end gas injection level 230 would look the same. In some embodiments, the angled apertures of the outlet end gas injection level 230 as rotated around the longitudinal axis of the gas distribution insert 200 (extending through the center of the inner channel 210 from the inlet end 201 to the outlet end 205. In some embodiments, the angled apertures of the outlet end gas injection level 230 are collectively rotated around the longitudinal axis by an amount about one half the spacing of the apertures in the inlet end gas injection level 220. For example, in the illustrated embodiment, there are six angled apertures evenly spaced (every 60º) around the inner channel 210, and the six angled apertures of the outlet end gas injection level 230 are evenly spaced (every 60º) around the inner channel 210 but offset from the angled apertures of the inlet end gas injection level 220 by 30º. The skilled artisan will recognize that this is merely one possible configuration and that other configurations are within the scope of the disclosure. For example, if there are three gas injection levels above the outlet end gas injection level 230, and each of the three gas injection levels have six evenly spaced openings, each of the three gas injection levels could be offset by 20º from each other.

The angle that the apertures direct gas flows into the inner channel 210 can impact the mixing and vortex efficiencies. In some embodiments, the angled apertures 225, 235 of one or more of the inlet end gas injection level 220 and outlet end gas injection level 230 are angled tangential to channel wall 211 of the inner channel 210. The skilled artisan will be aware of the geometric nature of a tangent line to the circular cross-section of the inner channel 210. As used in this specification and the appended claims, an angled aperture is tangential if a longitudinal axis of the aperture intersects of touches the cross-sectional radius of the inner channel 210 at an angle within ±2º, ±1º or ±0.5º of perpendicular (i.e., 90º). Stated differently, the longitudinal axis of the angled apertures intersects or touches the cross-sectional radius of the inner channel 210 at an angle in the range of 88-92º, or 89-91º, or 89.5-90.5º.

As illustrated, the angled apertures of the injection levels are angled inwardly toward the inner channel 210 while remaining substantially perpendicular to the longitudinal axis of the inner channel 210. In some embodiments, at least one of the angled apertures is further angled toward the outlet end 205 and gas distribution insert 200. In some embodiments, the plurality of angled apertures 225, 235 in one or more of the inlet end gas injection level 220 or outlet end gas injection level 230 are angled toward the outlet end 205 of the gas distribution insert 200 and connect to the inner channel 210 tangential to the channel wall 211.

In some embodiments, the angled apertures of the various injection levels have a diameter in the range of 0.25 mm to 5 mm, or in the range of 0.5 mm to 4.5 mm, or in the range of 0.75 mm to 4 mm, or in the range of 1 mm to 3.5 mm, or in the range of 1.5 mm to 3.25 mm, or in the range of 2 mm to 3 mm. In some embodiments, the angled apertures 245 of the outlet end gas injection level 230 have a smaller diameter than the angled apertures 225 of the inlet end gas injection level 220 or the angled apertures 235 of the outlet end gas injection level 230.

In the prior art gas distribution assembly shown in FIG. 2, the plurality of gas openings 208 are arranged in an ordered pattern. In FIG. 2, the plurality of gas openings 208 are in a linear pattern that establish a laminar flow in the gas distribution insert 200. According to embodiments of the present disclosure as shown in FIGS. 3, 4, and 6, the present disclosure provides a plurality of randomly oriented gas openings 208a, 208b, 208c and 208d extending through the thickness of the inlet end wall. As can be seen in FIGS. 3, 4, and 6, there is no fixed pattern to the randomly oriented gas openings 208a, 208b, 208c, and 208d.

The plurality of randomly oriented gas openings 208a, 208b, 208c and 208d have random angular orientations with respect to the inlet wall end face 204. It will be appreciated that FIG. 3 is a side view and FIG. 4 is a cross-sectional view, both showing the plurality of randomly oriented gas openings 208a-d comprising four gas openings. In. FIG. 6 is an isometric view of the gas insert of FIG. 3, the internal structure of which is shown in dotted lines. In addition, a central portion of the inlet end wall 206 is cut away and removed to better shown the plurality of randomly oriented gas openings 208x, where represents from 10-300 randomly oriented gas openings that are not arranged in any fixed pattern and have a random angular orientation with respect to the inlet wall end face 204. In one or more embodiments, the angular orientation of the plurality of randomly oriented gas openings are at an angle in a range of from 1 to 20 degrees, 2 to 20 degrees, 3 to 20 degrees, 4 to 20 degrees, 5 to 20 degrees, 1 to 10 degrees, 2 to 10 degrees, 3 to 10 degrees, 4 to 10 degrees, 5 to 10 degrees, 1 to 5 degrees, 1 to 4 degrees, 1 to 3 degrees or 1 to 2 degrees with respect a plane 290 perpendicular to the inlet wall end face 204.

The gas distribution insert 200 has an inlet end 201 with an inlet end wall 206 with an inlet wall end face 204 and an inlet end inner channel face within the inner channel 210, and an outlet end 205 with an outlet end face 209. In some embodiments, the inlet end wall 206 comprises a plurality of randomly oriented gas openings 208x extending through the inlet end wall 206. Stated differently, the inner channel 210 has an inlet end 201 having an inlet end wall 206 with a plurality of randomly oriented gas openings 208x extending therethrough.

The inner channel 210 extends from the inner channel face of the inlet end wall 206 to the outlet end 205 with an opening 212 in the outlet end face 209. The inner channel 210 is bounded by the channel wall 211.

In the illustrated embodiments, the inner channel 210 comprises an upper portion 214 and a lower portion 216. The upper portion 214 extends an upper portion length from the inlet end wall 206 to the lower portion 216. The upper portion 214 of some embodiments has a substantially uniform inner diameter along the upper portion 214 length. The lower portion 216 of the inner channel 210 has a flared profile, as shown in the Figures, with an increasing diameter from the upper portion 214 to the outlet end face 209. The transition from the upper portion 214 to the lower portion 216 occurs at the point where the channel wall 211 of the inner channel 210 changes from a uniform inner diameter to an increasing inner diameter. The upper portion 214 and lower portion 216 align with the upper portion 202 and lower portion 203 of the gas distribution insert 200.

Referring to FIGS. 2 and 3, in some embodiments, the outer peripheral surface 207 of the gas distribution insert 200 includes one or more peripheral channels 250 formed therein. The one or more peripheral channel 250 is a recessed portion of the outer peripheral surface 207 configured to hold an O-ring 251. In the embodiment shown, there are four peripheral channels 250 spaced above and below each of the inlet end gas injection level 220, the outlet end gas injection level 230 and the outlet end gas injection level 230. The one or more peripheral channel 250 have O-rings 251 that aid in the formation of a fluid-tight seal between the various gas injection levels to minimize or eliminate leakage.

In some embodiments, as shown in FIGS. 2-4, the inlet end 201 of the gas distribution insert 200 comprises a flange 218 extending outwardly from the outer peripheral surface 207 of the gas distribution insert 200. In the embodiment illustrated, the flange 218 is part of the inlet end wall 206.

In use, the outlet end face 209 of the outlet end 205 of the gas distribution insert 200 is in contact with the back surface 122 of the backing plate 120. The gas distribution insert 200 can be connected to the backing plate 120 by any suitable fastener or connection type known to the skilled artisan.

Operation of the gas distribution insert 200 in use is described with respect to the randomly oriented gas openings 208x in the Figures. A first gas is flowed through inlet line 229 in fluid communication with the inlet end gas injection level 220 through the gas manifold 195. A second gas is flowed through inlet line 239 in fluid communication with the outlet end gas injection level 230 through the gas manifold 195. The second gas and the first gas can be the same or different. A third gas can be flowed through a third inlet line 249 in fluid communication through the gas manifold 195. The third gas can be the same as one or more of the first gas or second gas, or different from both the first gas and second gas. In some embodiments, the third gas is an inert or diluent gas.

Some embodiments of the semiconductor manufacturing processing chamber 100 further comprise a remote plasma source (RPS) 185 connected to the gas manifold 195. In use, a plasma generated in the remote plasma source 185 flows through the plurality of randomly oriented gas openings 208x in the inlet end wall 206 of the gas distribution insert 200 into the inner channel 210 and the gas box plenum 129. In some embodiments, an inert gas purge line (not shown) is connected to the inner channel 210 of the gas distribution insert 200 (i.e., between the inlet end wall 206 and the inlet end gas injection level 220) to provide a continuous inert gas purge to prevent back streaming of gases to the remote plasma source 185. In some embodiments, inclusion of the inert gas purge eliminates the need for an isolation valve through continuous inert gas purge.

In some embodiments that use a remote plasma source (RPS) 185, a gas is flowed from the remote plasma source 185 through the plurality of randomly oriented gas openings 208x into the inner channel 210, a first gas is flowed into the inlet end gas injection level 220, a second gas is flowed into the outlet end gas injection level 230 have the same composition, and a third gas is flowed into the outlet end gas injection level 230 or at a third gas injection level (not shown), where the reverse flow from the outlet end gas injection level 230 creates turbulence and mixes the gases together. In this configuration, the first gas and second gas (and possibly third gas) can be the same species or different species which may react with the gas from the remote plasma source 185 (if a reactive gas is flowed). The skilled artisan will recognize the various reactive and non-reactive gas flow streams possible with the various embodiments.

Referring again to FIG. 1, the semiconductor manufacturing processing chamber 100 comprises a substrate support 170 within the chamber interior 105. The substrate support 170 of some embodiments comprises a support body 171 positioned on a support shaft 172. The support body 171 has a support surface 173 configured to support a semiconductor wafer 108 for processing. The support shaft 172 of some embodiments is configured to move the support body 171 closer to/further from the gas distribution faceplate 130 and/or around a rotational axis 175 of the support shaft 172. During processing, the support surface 173 is spaced from the front surface 131 of the gas distribution faceplate 130 to form a process gap 109.

In some embodiments, the support body 171 includes a thermal element 174 configured to heat the semiconductor wafer 108 on the support surface 173. The thermal element 174 can be any suitable heating mechanism known to the skilled artisan. For example, in some embodiments, the thermal element 174 comprises a resistive heating element that is connected to a power supply (not shown) configured to apply power to the thermal element 174 to heat the support body 171. In some embodiments, the support body 171 includes an electrostatic chuck (ESC) (not shown). The skilled artisan will be familiar with the construction of the ESC and the manner in which the ESC is powered and employed.

In some embodiments, as shown in FIG. 1, the semiconductor manufacturing processing chamber 100 includes a radio-frequency (RF) shield 150. The RF shield 150 is a generally ring-shaped component that is positioned within the chamber interior 105 of the semiconductor manufacturing processing chamber 100 between the substrate support 170 and the sidewall 102. The RF shield 150 surrounds the support surface 173 of the substrate support 170 and helps to prevent reactive gases from flowing from the process gap 109 to the chamber interior 105 of the chamber body 101.

The RF shield 150 has a top end and a bottom end. The top end of some embodiments has a sloped surface configured to direct a gas flow toward the pumping ring 140. In some embodiments, the top end of the RF shield 150 has a top end surface that is coplanar with the support surface 173 of the substrate support 170. In some embodiments, where the top end surface of the RF shield 150 is sloped, as shown in the Figures, the highest point of the top end surface is coplanar with the support surface 173 of the substrate support 170. In some embodiments, the top end of the RF shield 150 has a top end surface that is below the level of the support surface 173.

A pumping ring 140 is positioned on a top surface of the choke plate 160. The pumping ring 140 has a front surface and a back surface defining a thickness of the pumping ring 140. In use, the back surface of the pumping ring 140 is positioned adjacent to or in contact with the front surface 131 of the gas distribution faceplate 130. In some embodiments, in use, the front surface of the pumping ring 140 is positioned in contact with the top surface of the choke plate 160.

The pumping ring 140 of some embodiments comprises a vacuum plenum configured to remove process gases from an interior of the processing chamber. The vacuum plenum is formed by the recess in the front surface of the pumping ring 140 when the front surface of the pumping ring 140 is adjacent another surface. For example, as shown in FIG. 1, when the pumping ring 140 is positioned so that the front surface is adjacent to or in contact with the choke plate 160 or sidewall 102, a pumping volume 145 is formed.

In some embodiments, the pumping ring 140 is connected to the backing plate 120 with a plurality of fasteners (not shown) that extend through the gas distribution faceplate 130. In some embodiments, bolting the backing plate 120 to the pumping ring 140 sandwiches the gas distribution faceplate 130 between the backing plate 120 and the pumping ring 140.

In some embodiments, at least one aperture 146 extends between the recess 143 in the front surface of the pumping ring 140 and a back surface of the pumping ring 140. In some embodiments, the at least one aperture 146 extends between a recess in the front surface of the pumping ring 140 and an inner face of the pumping ring 140. The at least one aperture 146 has a radius equal to a radius of the front surface opening of the angled openings in the gas distribution faceplate 130.

During use, the backing plate 120, gas distribution faceplate 130 and pumping ring 140, in addition to other components, may be separated by one or more O-rings to help maintain a fluid-tight seal for the processing chamber. In some embodiments, the gas distribution assembly 110 includes a plurality of O-rings positioned between the backing plate 120 and the gas distribution faceplate 130 and/or a plurality of O-rings positioned between the gas distribution faceplate 130 and the pumping ring 140. In some embodiments, the pumping ring 140 is connected to the choke plate 160 with at least one O-ring positioned between.

Advantageously, one or more embodiments of the present disclosure provides improved mixing by injecting gas from an inlet end face and inlet end wall that comprises a plurality of openings in random directions to break laminarity of gas flow into turbulent gas flow, which enhances mixing efficiency before entering the funnel cavity. Additionally, the gas insert comprises of a plurality of gas injection levels comprising a peripheral recess in an outer peripheral wall of the gas insert, each of the peripheral recesses having a plurality of angled apertures extending from a bottom surface of the peripheral recess to the inner channel, thus allowing flow to be directed in a rotational direction within the inner channel. Embodiments of the disclosure provide better mixing without having a physical mixer, eliminating the attendant disadvantages of a physical mixer in ALD processes such as providing cold spots in the cap insert and limiting fast purging.

Thus, in one or more embodiments, the randomly oriented gas openings 208x are configured to generate turbulent gas flow in the inner gas channel. The randomly oriented gas openings comprise conduits having a variety of angular orientations with respect to the inlet wall end wall face 204, which is shown as a plane 290 perpendicular to the inlet end wall face. In some embodiments, the randomly oriented gas openings comprise conduits having a variety of opening diameters. In other embodiments, the randomly oriented gas openings comprise conduits having a variety of opening diameters and a variety of angular orientations with respect to the inlet end wall face.

In some embodiments, the at least two gas inlets generate a vortex in the inner gas channel, and the randomly oriented gas openings enhances mixing efficiency of large and small gas molecules flowing through the inner gas channel. In some embodiments, there are two gas inlets arranged at equally spaced angles relative to a central axis of the inner gas channel. In some embodiments, there are at least three inlets arranged at equally spaced angles relative to a central axis of the inner gas channel to create a swirling flow pattern. In some embodiments, each of the at least two gas inlets are configured to flow a different gas. In some embodiments, at least one of the two gas inlets is radially aligned with the inlet end of the inner gas channel. In some embodiments, there are three gas inlets and each of the three gas inlets include three inlets that are radially aligned with inlet end of the inner gas channel.

In some embodiments, there is a plurality of gas injection levels, each gas injection level comprising the at least two gas inlets extending through the inner gas channel sidewall and configured to provide a gas flow to the inner gas channel, each of the gas flows is directed in a rotational direction within the inner gas channel, and wherein there is a gas injection level closest to the outlet end of the gas distribution insert configured to direct a gas flow in an opposite rotational direction than the gas injection levels further from the outlet end of the gas distribution insert. In some embodiments, there are three gas injection levels including an inlet end gas injection level closest to the inlet end of the gas distribution insert, an intermediate gas injection level, and an outlet end gas injection level, and gas injection level closest to the outlet end of the gas distribution insert.

Another aspect of the disclosure pertains to a gas distribution apparatus comprising the gas distribution insert described herein and further comprising a gas distribution faceplate having a top surface and a bottom surface with a plurality of apertures extending through the gas distribution faceplate from the top surface to the bottom surface and in flow communication with the gas distribution insert. Yet another aspect pertains to a semiconductor manufacturing processing chamber comprising the gas distribution apparatus described herein.

Another aspect pertains to a method of processing a substrate in a semiconductor manufacturing processing chamber comprising flowing a processing gas through the gas distribution insert described herein. In one embodiment of the method, the method further comprises flowing a first processing gas including gas molecules having a first size and flowing a second processing gas including gas molecules having a second size larger than the first size, wherein the randomly oriented gas openings enhance a mixing efficiency of the first processing gas having a first size and the second processing gas having the second size. and small gas molecules flowing through the inner gas channel. In some embodiments, the randomly oriented gas openings comprise conduits having a variety of angular orientations with respect to the inlet end wall face. In some embodiments, the randomly oriented gas openings comprise conduits having a variety of opening diameters. In some embodiments the randomly oriented gas openings comprise conduits having a variety of opening diameters and a variety of angular orientations with respect to the inlet end wall face.

Reference throughout this specification to "one embodiment," "certain embodiments," "one or more embodiments" or "an embodiment" means that a particular feature, structure, material, or characteristic described in connection with the embodiment is included in at least one embodiment of the disclosure. Thus, the appearances of the phrases such as "in one or more embodiments," "in certain embodiments," "in one embodiment" or "in an embodiment" in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A gas distribution insert configured to deliver a gas in a semiconductor manufacturing processing chamber, the gas distribution insert comprising:
a gas distribution insert inlet end and a gas distribution insert outlet end defining a gas distribution insert length, the insert inlet end including an inlet end wall including an inlet end wall face and an outlet end wall face, the inlet end wall face and the outlet end wall face defining a thickness of the inlet end wall;
a plurality of randomly oriented gas openings extending through the thickness of the inlet end wall;
an inner gas channel extending from the outlet end wall face to the insert outlet end, the inner gas channel bounded by an inner gas channel sidewall; and
at least two gas inlets extending through the inner gas channel sidewall.

2. The gas distribution insert of claim 1, wherein the randomly oriented gas openings are configured to generate turbulent gas flow in the inner gas channel.

3. The gas distribution insert of claim 2, wherein the randomly oriented gas openings comprise conduits having a variety of angular orientations with respect to the inlet end wall face.

4. The gas distribution insert of claim 2, wherein the randomly oriented gas openings comprise conduits having a variety of opening diameters.

5. The gas distribution insert of claim 2, wherein the randomly oriented gas openings comprise conduits having a variety of opening diameters and a variety of angular orientations with respect to the outlet end wall face.

6. The gas distribution insert of claim 2, wherein the at least two gas inlets generate a vortex in the inner gas channel, and the randomly oriented gas openings enhances mixing efficiency of large and small gas molecules flowing through the inner gas channel.

7. The gas distribution insert of claim 2, wherein there are two gas inlets arranged at equally spaced angles relative to a central axis of the inner gas channel.

8. The gas distribution insert of claim 2, wherein there are at least three inlets arranged at equally spaced angles relative to a central axis of the inner gas channel to create a swirling flow pattern.

9. The gas distribution insert of claim 2, wherein each of the at least two gas inlets are configured to flow a different gas.

10. The gas distribution insert of claim 2, wherein at least one of the two gas inlets is radially aligned with the inlet end of the inner gas channel.

11. The gas distribution insert of claim 10, wherein there are three gas inlets and each of the three gas inlets include three inlets that are radially aligned with inlet end of the inner gas channel.

12. The gas distribution insert of claim 2, further comprising a plurality of gas injection levels, each gas injection level comprising the at least two gas inlets extending through the inner gas channel sidewall and configured to provide a gas flow to the inner gas channel, each of the gas flows is directed in a rotational direction within the inner gas channel, and wherein there is a gas injection level closest to the outlet end of the gas distribution insert configured to direct a gas flow in an opposite rotational direction than the gas injection levels further from the outlet end of the gas distribution insert.

13. The gas distribution insert of claim 12, wherein there are three gas injection levels including an inlet end gas injection level closest to the inlet end of the gas distribution insert, an outlet end gas injection level, and an outlet end gas injection level, and gas injection level closest to the outlet end of the gas distribution insert.

14. A gas distribution apparatus comprising the gas distribution insert of claim 1, and further comprising a gas distribution faceplate having a top surface and a bottom surface with a plurality of apertures extending through the gas distribution faceplate from the top surface to the bottom surface and in flow communication with the gas distribution insert.

15. A semiconductor manufacturing processing chamber comprising the gas distribution apparatus of claim 14.

16. A method of processing a substrate in a semiconductor manufacturing processing chamber comprising flowing a processing gas through the gas distribution insert of claim 1.

17. The method of claim 16, further comprising flowing a first processing gas including gas molecules having a first size and flowing a second processing gas including gas molecules having a second size larger than the first size, wherein the randomly oriented gas openings enhance a mixing efficiency of the first processing gas having a first size and the second processing gas having the second size. and small gas molecules flowing through the inner gas channel.

18. The method of claim 17, wherein the randomly oriented gas openings comprise conduits having a variety of angular orientations with respect to the inlet end wall face.

19. The method of claim 17, wherein the randomly oriented gas openings comprise conduits having a variety of opening diameters.

20. The method of claim 17, wherein the randomly oriented gas openings comprise conduits having a variety of opening diameters and a variety of angular orientations with respect to the inlet end wall face.
